(19) United States
(12) Patent Application Publication
(10) Pub. No.: US 2007/0045649 A1
(43) Pub. Date: Mar. 1, 2007

(54) Light source device

(75) Inventor: Jung-Yao Chen, Taoyuan City (TW)

Correspondence Address: RABIN & Berdo, PC, 1101 14TH STREET, NW, SUITE 500, WASHINGTON, DC, 20005, US

(73) Assignee: BenQ Corporation, Taoyuan Shien (TW)

(21) Appl. No.: 11/504,729

(22) Filed: Aug. 16, 2006

(30) Foreign Application Priority Data
Aug. 23, 2005 (TW) 94128819

(51) Int. Cl. H01L 33/00

(52) U.S. Cl. 257/99

(57) ABSTRACT

A light source device including a substrate, a first LED chip, a second LED chip, a third LED chip and a light guide element is provided. The first LED chip is disposed on one side of the substrate. The second LED chip is disposed on the other side of the substrate. The third LED chip is disposed above the substrate. The light guide element has a first light-receiving surface corresponding to the first LED chip, a second light-receiving surface corresponding to the second LED chip, a third light-receiving surface corresponding to the third LED chip, and a light-emitting surface. The light guide element correspondingly receives and mixes the light emitted by the first LED chip, the second LED chip and the third LED chip via the first light-receiving surface, the second light-receiving surface and the third light-receiving surface, and then projects the mixed light via the light-emitting surface.

This application claims the benefit of Taiwan application Serial No. 94128819, filed Aug. 23, 2005, the subject matter of which is incorporated herein by reference.

### BACKGROUND OF THE INVENTION

1. Field of the Invention

The invention relates in general to a light source device, and more particularly to a light source device capable of mixing the light emitted by three light emitting diode (LED) chips by a light guide element to provide an all-directional and uniformed white light.

2. Description of the Related Art

The light source device currently applied in a backlight module or an image projecting device typically provides the light by a lamp tube, such as a cold cathode fluorescent lamp (CCFL) or a hot cathode fluorescent lamp (HCFL).

However, the cold cathode fluorescent lamp or the hot cathode fluorescent lamp includes environmental unfriendly material such as mercury which is difficult to be recycled and would pollute the environment easily.

Along with the global awareness of environmental conservation and the recyclability of electronic products, the backlight module using the cold cathode fluorescent lamp or the hot cathode fluorescent lamp containing mercury as the light source goes against environmental conservation and would largely reduce the practicality of the light source device.

### SUMMARY OF THE INVENTION

It is therefore an object of the invention to provide a light source device capable of achieving an excellent light-mixing effect and providing an all-directional white light by using a light guide element to mix the light emitted by three light emitting diode (LED) chips. The present embodiment of the invention adopts LED chips as the light source not only avoids the problems of resource recycling and mercury pollution that a light source using a lamp tube would face but also complies with environmental conservation.

The invention achieves the above-identified-object by providing a light source device including a substrate, a first LED chip, a second LED chip, a third LED chip and a light guide element. The first LED chip is disposed on one side of the substrate. The second LED chip corresponding to the first LED is disposed on the other side of the substrate. The third LED chip positioned between the first LED chip and the second LED chip is disposed above the substrate. The light guide element positioned between the first LED chip and the second LED chip is disposed above the third LED. The light guide element has a first light-receiving surface corresponding to the first LED chip, a second light-receiving surface corresponding to the second LED chip, a third light-receiving surface corresponding to the third LED chip, and a light-emitting surface. The light guide element correspondingly receives and mixes the light emitted by the first LED chip, the second LED chip and the third LED chip via the first light-receiving surface, the second light-receiving surface and the third light-receiving surface, and then projects the mixed light via the light-emitting surface.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a cross-sectional view of a light source device according to a preferred embodiment of the invention; and

FIG. 2 is a right side view of a substrate and a light guide element of FIG. 1.

### DETAILED DESCRIPTION OF THE INVENTION

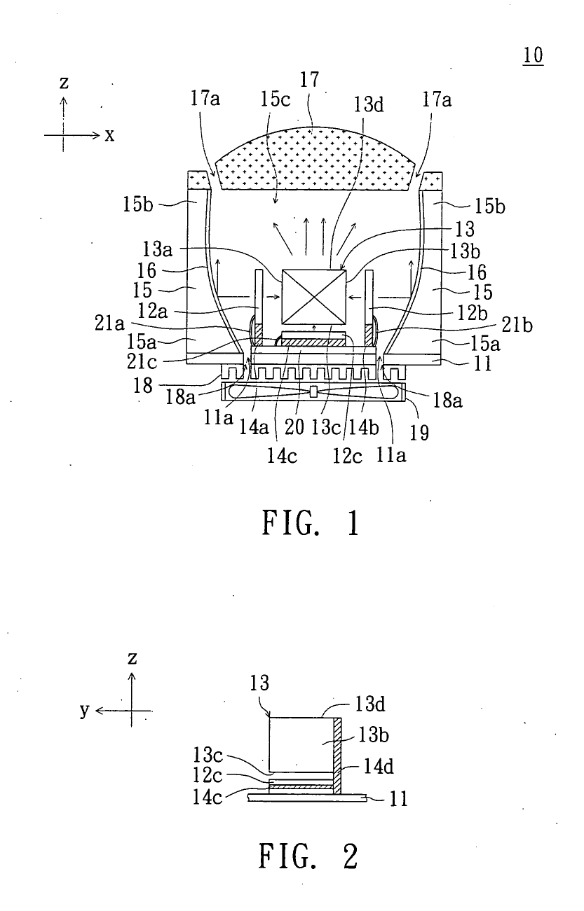

Referring to FIGS. 1-2. FIG. 1 is a cross-sectional view of a light source device according to an embodiment of the invention. FIG. 2 is a right side view of a substrate and a light guide element of FIG. 1. In FIGS. 1-2, the light source device 10 includes a substrate 11, a first light emitting diode (LED) chip 12a, a second LED chip 12b, a third LED chip 12c and a light guide element 13. The first LED chip 12a is disposed on one side of the substrate 11. The second LED chip 12b corresponding to the first LED chip 12a is disposed on the other side of the substrate 11. The third LED chip 12c positioned between the first LED chip 12a and the second LED chip 12b is disposed above the substrate 11. The light guide element 13 positioned between the first LED chip 12a and the second LED chip 12b is disposed above the third LED 12c. The light guide element 13 has a first light-receiving surface 13a, a second light-receiving surface 13b opposite to the first light-receiving surface 13a, a third light-receiving surface 13c, and a light-emitting surface 13d opposite to the third light-receiving surface 13c. The first light-receiving surface 13a and the second light-receiving surface 13b connect the third light-receiving surface 13c and the light-emitting surface 13d. The first light-receiving surface 13a corresponds to the first LED chip 12a. The second light-receiving surface 13b corresponds to the second LED chip 12b. The third light-receiving surface 13c corresponds to the third LED chip 12c. The light guide element 13 correspondingly receives and mixes the light emitted by the first LED chip 12a, the second LED chip 12b and the third LED chip 12c via the first light-receiving surface 13a, the second light-receiving surface 13b and the third light-receiving surface 13c, and then projects the mixed light via the light-emitting surface 13d.

As for how the first LED chip 12a, the second LED chip 12b, the third LED chip 12c and the light guide element 13 are disposed on the substrate 11 is disclosed below. However, the technology of the present embodiment of the invention is not limited thereto. For example, the light source device 10 further includes a first supporting element 14a, a second supporting element 14b, a third supporting element 14c and a fourth supporting element 14d. The first supporting element 14a, the second supporting element 14b, the third supporting element 14c and the fourth supporting element 14d are interspaced and disposed on the substrate 11 for respectively supporting the first LED chip 12a, the second LED chip 12b, the third LED chip 12c and the light guide element 13 to be above the substrate 11.

In the present embodiment of the invention, the light source device 10 further includes a dam 15. The dam 15 has a bottom portion 15a, a top portion 15b and an accommodation space 15c penetrating through bottom portion 15a and the top portion 15b. The bottom portion 15a can be connected to the substrate 11 via an adhesive or an engaging mechanism. The accommodation space 15c is used for accommodating the first LED chip 12a, the second LED chip 12b, the third LED chip 12c, the light guide element 13, the first supporting element 14a, the second supporting element 14b, the third supporting element 14c and the fourth supporting element 14d. The dam 15 may include a reflective metal or alloy, such as high reflective aluminum, for reflecting the light. In order to enhance the reflecting ability of the dam 15, the light source device 10 further includes a reflective material 16 disposed on the inner-wall of the dam 15 for reflecting the light. The reflective material 16 is disposed on the inner-wall of the dam 15 and in the accommodation space 15c via pasting or adhering.

The light source device 10 further includes a lens 17. The lens 17 may be connected to the top portion 15b and positioned on the light-emitting surface 13d of the light guide element 13 via an adhesive or an engaging mechanism for sealing an opening at the top of the accommodation space 15c to increase the light diffusion effect. The top surface of the lens 17 is a convex surface, so that the lens 17 is a concave lens with respect to the light emitted by the light guide element 13. To enhance the heat dissipation of the light source device 10, the lens 17 or the dam 15 further has at least a first heat dissipation hole 17a. The present embodiment of the invention is exemplified by the first heat dissipation hole 17a of the lens 17. The substrate 11 has at least a second heat dissipation hole 11a. Moreover, the light source device 10 further includes a heat spreader 18. The heat spreader 18 is disposed under the substrate 11 and has at least a third heat dissipation hole 18a. The third heat dissipation hole 18a corresponds to the second heat dissipation hole 1a. Examples of the heat spreader 18 include a dissipation fin. Furthermore, the light source device 10 further includes a fan 19. The fan 19 is disposed under the heat spreader 18 and corresponds to the third heat dissipation hole 18a. Through circuit design, the rotation speed of the fan 19 may be adjusted according to the temperature of the light source device 10. Alternatively, the light source device 10 can do the heat spreader 18 and can directly dispose the fan 19 under the substrate 11 to correspond to the second heat dissipation hole 11a. Therefore, the light source device 10 can achieve heat dissipation through various combination of the heat dissipation hole, the heat spreader and the fan for enabling the first LED chip 12a, the second LED chip 12b, and the third LED chip 12c to maintain excellent illuminating quality under appropriate temperatures.

As for how the first LED chip 12a, the second LED chip 12b, the third LED chip 12c are electrically connected to an external power source to illuminate is disclosed below. However, the technology of the present embodiment of the invention is not limited thereto. For example, the light source device 10 further includes a circuit board 20. The circuit board 20 is disposed on the substrate 11 for being electrically connected to the first LED chip 12a, the second LED chip 12b and the third LED chip 12c. Therefore, after having received an external power source, the circuit board 20 provides power to the first LED chip 12a, the second LED chip 12b and the third LED chip 12c for enabling the first LED chip 12a, the second LED chip 12b and the third LED chip 12c to emit a light to the light guide element 13. If the first supporting element 14a, the second supporting element 14b and the third supporting element 14c include three metal supporting elements, the first LED chip 12a, the second LED chip 12b and the third LED chip 12c may be electrically connected to the circuit board 20 respectively via a conductive wire and a metal supporting element. For example, the first LED chip 12a is electrically connected to the circuit board 20 via a first conductive wire 21a and the first supporting element 14a, the second LED chip 12b is electrically connected to the circuit board 20 via a second conductive wire 21b and the second supporting element 14b, and the third LED chip 12c is electrically connected to the circuit board 20 via a third conductive wire 21c and the third supporting element 14c. The positive terminals of the first LED chip 12a, the second LED chip 12b and the third LED chip 12c are correspondingly and electrically connected to three metal supporting elements, namely, the first supporting element 14a, the second supporting element 14b and the third supporting element 14c. Or, the negative terminals of the first LED chip 12a, the second LED chip 12b and the third LED chip 12c may be correspondingly and electrically connected to the three metal supporting elements, namely, the first supporting element 14a, the second supporting element 14b and the third supporting element 14c. Moreover, the first LED chip 12a, the second LED chip 12b and the third LED chip 12c may be electrically connected to the circuit board 20 respectively via two conductive wires.

However, any one who is skilled in the technology of the present embodiment of the invention will understand that the technology of the present embodiment of the invention is not limited thereto. For example, the light guide element 14 includes an X-cube or a dichroic prism. Besides, the substrate 11 may includes a metal substrate or a sapphire the substrate to dissipate the heat from the light source device 10. If the first LED chip 12a, the second LED chip 12b and the third LED chip 12c include the combination of a red (R) LED chip, a green (G) LED chip and a blue (B) LED chip, then the light guide element 13 is able to mix the red light, the green light and the blue light and project the mixed white light via the light-emitting surface 13d. Moreover, the first LED chip 12a, the second LED chip 12b and the third LED chip 12c are three white light LED chips or other color LED chips. The light source device 10 may be applied in a backlight module, an image fetching device or an advertisement sight board.

The present embodiment of the invention further arranges a number of light source devices 10 in a row, a column or an array matrix to provide a larger area of planar backlight.

The light source device disclosed in above embodiment of the invention is capable of achieving an excellent light-mixing effect and providing an all-directional white light by using a light guide element to mix the light emitted by three LED chips. That the present embodiment of the invention adopts LED chips as the light source not only avoids the problems of resource recycling and mercury pollution that a light source using a lamp tube would face but also complies with environmental conservation.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light source device, comprising:
a substrate;
a first light emitting diode (LED) chip disposed on the one side of the substrate;
a second LED chip corresponding to the first LED chip and disposed on the other side of the substrate;
a third LED chip positioned between the first LED chip and the second LED chip and disposed above the substrate; and
a light guide element positioned between the first LED chip and the second LED chip and disposed on the third LED, wherein the light guide element, having respectively a first light-receiving surface corresponding to the first LED chip, a second light-receiving surface corresponding to the second LED chip, a third light-receiving surface corresponding to the third LED chip, and a light-emitting surface, correspondingly receives and mixes the light emitted by the first LED chip, the second LED chip and the third LED chip via the first light-receiving surface, the second light-receiving surface and the third light-receiving surface, and then projects the mixed light via the light-emitting surface.

2. The light source device according to claim 1, further comprising:
a first supporting element, a second supporting element, a third supporting element and a fourth supporting element disposed on the substrate for respectively supporting the first LED chip, the second LED chip, the third LED chip and the light guide element to be above the substrate.

3. The light source device according to claim 2, further comprising:
a dam having a bottom portion, a top portion and an accommodation space penetrating through the bottom portion and the top portion, wherein the bottom portion is connected to the substrate, and the accommodation space is used for accommodating the first LED chip, the second LED chip, the third LED chip, the light guide element, the first supporting element, the second supporting element, the third supporting element and the fourth supporting element.

4. The light source device according to claim 3, wherein the dam comprises a reflective metal or alloy.

5. The light source device according to claim 3, further comprising:
a reflective material disposed on the inner-wall of the dam.

6. The light source device according to claim 3, further comprising:
a lens connected to the top portion for sealing an opening at the top of the accommodation space.

7. The light source device according to claim 6, wherein the lens or the dam has a first heat dissipation hole, and the substrate has a second heat dissipation hole.

8. The light source device according to claim 7, further comprising:
a heat spreader disposed under the substrate, wherein the heat spreader has a third heat dissipation hole corresponding to the second heat dissipation hole.

9. The light source device according to claim 8, further comprising:
a fan disposed under the heat spreader and corresponding to the third heat dissipation hole.

10. The light source device according to claim 7, further comprising:
a fan disposed under the substrate and corresponding to the second heat dissipation hole.

11. The light source device according to claim 1, further comprising:
a circuit board disposed on the substrate for being electrically connected to the first LED chip, the second LED chip and the third LED chip.

12. The light source device according to claim 11, wherein the first LED chip, the second LED chip and the third LED chip are electrically connected to the circuit board respectively via two conductive wires.

13. The light source device according to claim 11, wherein the first supporting element, the second supporting element and the third supporting element comprise three metal supporting elements, and the first LED chip, the second LED chip and the third LED chip are electrically connected to the circuit board respectively via a conductive wire and a metal supporting element.

14. The light source device according to claim 13, wherein the positive terminals of the first LED chip, the second LED chip and the third LED chip are electrically connected to the three metal supporting elements correspondingly.

15. The light source device according to claim 13, wherein the negative terminals of the first LED chip, the second LED chip and the third LED chip are electrically connected to the three metal supporting elements correspondingly.

16. The light source device according to claim 1, wherein the light guide element comprises an X-cube or a dichroic prism.

17. The light source device according to claim 1, wherein the first LED chip, the second LED chip and the third LED chip comprises the combination of a red (R) LED chip, a green (G) LED chip and a blue (B) LED chip.

18. The light source device according to claim 1, wherein the first LED chip, the second LED chip and the third LED chip are three white LED chips.

19. The light source device according to claim 1, wherein the substrate comprises a metal substrate or a sapphire substrate.
